(19) United States
(12) Patent Application Publication
(10) Pub. No.: US 2018/0299792 A1
(43) Pub. Date: Oct. 18, 2018

(54) FILTER, METHOD OF FORMATION THEREOF, AND IMAGE SENSOR

(71) Applicant: ASML Netherlands B.V., Veldhoven (NL)

(72) Inventors: Jelte Rients BEARDA, Son en Breugel (NL); Joost André KLUGKIST, Waalre (NL); Robbert Jan VOOGD, Achel (BE); Guido HERGENHAN, Großlöbichau (DE); Meik PANITZ, Weimar (DE); Jochen TAUBERT, Jena (DE)

(73) Assignee: ASML Netherlands B.V., Veldhoven (NL)

(21) Appl. No.: 15/569,384

(22) PCT Filed: May 4, 2016
(86) PCT No.: PCT/EP2016/059957

§ 371 Date: Oct. 25, 2017

(30) Foreign Application Priority Data
Jun. 2, 2015 (EP) 15170335.2

(51) Int. Cl. G03F 7/20; G02B 5/20; F21V 9/32; H04N 5/225

(52) U.S. Cl. CPC G03F 7/70625; H04N 5/2252; F21V 9/32; G02B 5/201

(57) ABSTRACT

A method of forming a radiation filter for a lithographic system, the method including forming at least one structure in or on a filter body, wherein the at least one structure provides a filtering effect and least one of a), b), c) or d): a) the at least one structure includes a plurality of transmissive, reflective, absorbing or fluorescent structures, and the method includes providing a desired distribution of the structures to provide a desired filtering effect; b) forming the at least one structure includes forming at least one transmissive, absorbing, reflective or fluorescent layer that has a variable thickness; c) forming the at least one structure includes altering at least one optical property to provide a variation of the optical property with position; d) the at least one structure includes a fluorescent layer that provides variation of at least one fluorescence property with position and/or angle of incidence.

### CROSS REFERENCE TO RELATED APPLICATIONS

This application claims priority of EP application 15170335.2 which was filed on Jun. 2, 2015 and which is incorporated herein in its entirety by reference.

### FIELD

The present invention relates to filter, for example a filter used in a sensor of a lithographic apparatus, and a method of forming such filter.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g. a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

It is known to use image sensors to perform various image measurements, for example at the image plane or substrate table of the lithographic apparatus or at other locations in a lithographic system. However, conventional image sensing optics often do not uniformly illuminate the image plane that contains sensor elements of the image sensor (which may, for example, comprise a two-dimensional array with rows and columns of detector pixels). During operation, the exposure may be adjusted such that detector pixels that receive the highest illumination do not reach a saturation level. However, this means that the pixels that received the lowest radiation dose will receive a dose that lies well below the saturation level. Consequently, the signal-to-noise ratio for these pixels will be worse than that for the pixels that receive a high dose.

Filters with variable transmissivity have been suggested. It may be desirable to provide filters with properties that are well-suited to lithographic applications, and to provide improved or at least alternative methods of producing filters or similar components.

### SUMMARY

In a first aspect of the invention there is provided a method of forming a radiation filter for use in a lithographic system comprising:

obtaining a filter body and forming at least one structure in or on the body, wherein the at least one structure provides a filtering effect and at least one of a), b), c) or d):
a) the at least one structure comprises a plurality of transmissive, reflective, absorbing or fluorescent structures, and the method comprises providing a desired distribution of the structures to provide a desired filtering effect;
b) forming the at least one structure comprises forming at least one transmissive, absorbing, reflective or fluorescent layer that has a variable thickness;
c) forming the at least one structure comprises altering at least one optical property to provide a variation of the optical property with position;
d) the structure comprises a fluorescent layer that provides variation of at least one fluorescence property with position and/or angle of incidence.

The at least one structure may be formed directly on a surface of the body, or there may be intervening layers or other components between the at least one structure and the body.

The forming of the at least one associated structure may comprise depositing the structure on the filter body.

The providing of a desired distribution of the structures may comprise providing a desired concentration of the structures as a function of position. Each of the structures has substantially the same thickness. The filter may comprise a digital filter.

The at least one transmissive, absorbing, reflective or fluorescent layer may have a thickness that varies substantially continuously with position.

The forming of the at least one structure may comprise providing a mask and depositing material through at least one orifice of the mask.

The method may comprise providing a gap between the at least one orifice and a surface on which the material is to be deposited. The surface may be a surface of the filter body, or the surface of a further layer provided on the filter body.

The size of the gap and/or the size of the orifice may be selected to provided a desired distribution of the material on the surface.

Said at least one orifice may have at least one side wall of a desired shape and/or thickness selected to provide a desired distribution of the material on the surface.

At least part of said at least one side wall may be inclined at a selected angle to the surface. The at least one side wall may be not perpendicular to the surface.

The forming of the transmissive, absorbing, reflective or fluorescent layer may comprise selectively altering the thickness of the layer as a function of position.

The altering of the thickness of the layer may comprise removal of at least part of the layer. The method may comprise using an ion beam process to alter the thickness of the layer.

The structure may comprise a layer of material on or of the body, and the altering of the at least one optical property may comprise applying electromagnetic radiation to the layer of material and/or performing a chemical treatment at the layer of material.

The altering of the at least one optical property may comprise selectively applying laser radiation to the layer of material.

The selective applying of the laser radiation may be performed in the presence of a selected gas such that application of the laser radiation causes local reaction of the optically transmissive or optically absorbing layer with a component of the gas. The gas may comprise oxygen gas.

The altering of the at least one optical property may comprise selectively performing a photo-activated chemical reaction at the layer of material.

The altering of the at least one optical property may comprise selectively oxidising the layer and/or selectively bleaching the layer.

The altering of the at least one optical property may comprise selectively altering the at least one optical property as a function of position.

The at least one optical property may comprise at least one of transmissivity, absorption, reflectivity or fluorescence.

The fluorescent layer may have a thickness selected to provide a desired variation of fluorescence with angle of incidence.

The fluorescent layer may have a thickness less than an absorption length of radiation at a selected wavelength.

The method may comprise providing the fluorescent layer with a thickness that varies as a function of position, thereby to provide a desired variation of fluorescence with position and/or angle of incidence.

The fluorescent layer may have a thickness less than an absorption length of radiation at a selected wavelength for at least some parts of the layer, and a thickness greater than an absorption length of radiation at a selected wavelength for at least some other parts of the layer. The fluorescent layer may be arranged such as to provide a variation of fluorescence efficiency with position.

The structure may comprise at least one of a metal structure, a semiconductor structure, a metal oxide structure or a metal nitride structure.

The metal layer may comprise, for example, Cr or Al. The semiconductor layer may comprise, for example, Si or Ge. The metal oxide layer or metal nitride layer may comprise, for example, TiN.

The filter may be configured to filter at least one of visible radiation, ultraviolet (UV) radiation and extreme ultraviolet (EUV) radiation.

In a further aspect of the invention, which may be provided independently there is provided a filter of a lithographic system, comprising a body and at least one structure in or on the body, wherein the at least one structure provides a filtering effect and least one of a), b), c) or d):

a) the at least one structure comprises a plurality of transmissive, reflective, absorbing or fluorescent structures distributed to provide a desired filtering effect;

b) the at least one structure comprises at least one transmissive, absorbing, reflective or fluorescent layer that has a variable thickness;

c) the at least one structure has a variation of at least one optical property with position;

d) the structure comprises a fluorescent layer that provides variation of at least one fluorescence property with position and/or angle of incidence.

The desired distribution of the structures may comprise a desired concentration of the structures as a function of position, and each of the structures may have substantially the same thickness. The filter may comprise a digital filter.

The at least one layer may have a thickness that varies continuously with position for at least a range of positions on the filter. The filter may comprise an analogue filter

The at least one structure may have a substantially constant thickness, and the optical property that varies with position may comprise at least one of transmissivity, absorption, reflectivity or fluorescence.

The fluorescent layer may have a thickness less than an absorption length of radiation at a filter wavelength for at least some positions on the filter.

In another aspect of the invention, there is provided a filter formed according to any method as claimed or described herein.

In a further aspect of the invention, there is provided an image sensor for a lithographic apparatus comprising a detector array and a filter as claimed or described herein or as formed using a method as claimed or described herein.

In another aspect of the invention, there is provided a lithographic apparatus comprising: an illumination system for providing a beam of radiation; a support structure for supporting a patterning device, the patterning device serving to impart the radiation beam with a pattern in its cross-section; a substrate table for holding a substrate; a projection system for projecting the patterned radiation beam to provide an image at the substrate table; and a sensor as claimed or described herein installed on the substrate table for sensing at least a region of the image

Features in one aspect may be provided as features in any other aspect as appropriate. For example, features of any one of a sensor, filter, apparatus or method may be provided as features of any one other of a sensor, filter, apparatus or method. Any feature or features in one aspect may be provided in combination with any suitable feature or features in any other aspect.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2A is a schematic illustration of a sensor apparatus in accordance with an embodiment;

FIG. 2B is a schematic illustration of a sensor apparatus in accordance with an alternative embodiment;

FIG. 3 is a schematic illustration of a filter according to an embodiment;

FIG. 4 is a schematic illustration of a filter according to an alternative embodiment;

FIGS. 5 to 11 are schematic illustrations of methods of forming filters according to various embodiments;

FIG. 12 is a schematic illustration of a filter according to an alternative embodiment;

FIG. 13 is a schematic illustration of a filter according to a further alternative embodiment; and

FIG. 14 is a graph of transmission of radiation as a function of absorption length of beams applied to a layer of fluorescent material.

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable minor arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small minors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The illumination system may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g. water, so as to fill a space between the final element of the projection system and the substrate Immersion techniques are well known in the art for increasing the numerical aperture of projection systems.

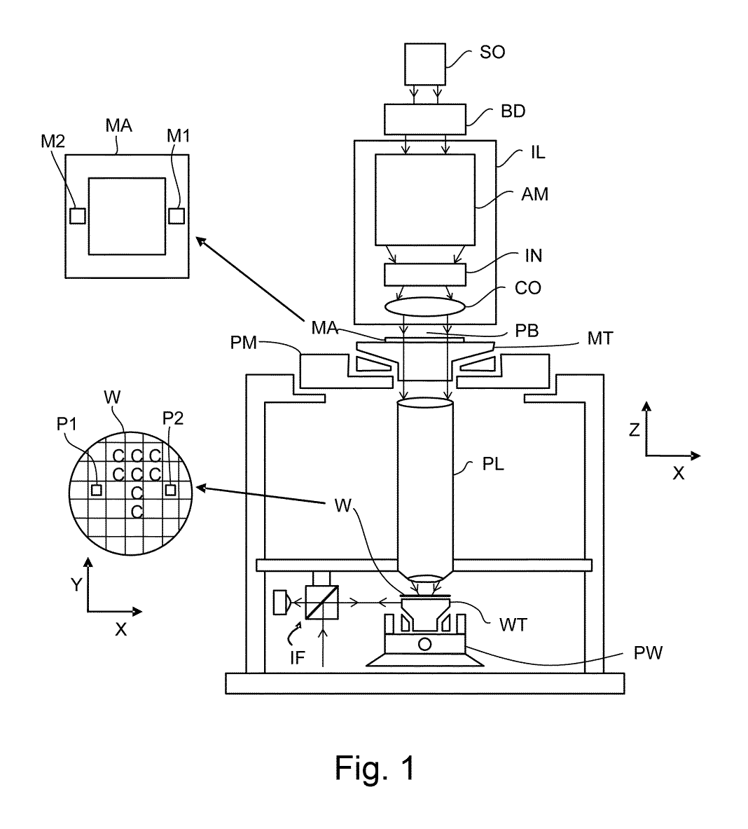

FIG. 1 schematically depicts a lithographic apparatus according to a particular embodiment of the invention. The apparatus comprises:

an illumination system (illuminator) IL to condition a beam PB of radiation (e.g. UV radiation or EUV radiation).

a support structure (e.g. a support structure) MT to support a patterning device (e.g. a mask) MA and connected to first positioning device PM to accurately position the patterning device with respect to item PL;

a substrate table (e.g. a wafer table) WT for holding a substrate (e.g. a resist coated wafer) W and connected to second positioning device PW for accurately positioning the substrate with respect to item PL; and

a projection system (e.g. a refractive projection lens) PL configured to image a pattern imparted to the radiation beam PB by patterning device MA onto a target portion C (e.g. comprising one or more dies) of the substrate W.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent (commonly referred to as -outer and -inner, respectively) of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross section.

The radiation beam PB is incident on the patterning device (e.g. mask) MA, which is held on the support structure MT. Having traversed the patterning device MA, the beam PB passes through the lens PL, which focuses the beam onto a target portion C of the substrate W. With the aid of the second positioning device PW and position sensor IF (e.g. an interferometric device), the substrate table WT can be moved accurately, e.g. so as to position different target portions C in the path of the beam PB. Similarly, the first positioning device PM and another position sensor (which is not explicitly depicted in FIG. 1) can be used to accurately position the patterning device MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The depicted apparatus can be used in the following preferred modes:
1. In step mode, the support structure MT and the substrate table WT are kept essentially stationary, while an entire pattern imparted to the beam PB is projected onto a target portion C in one go (i.e. a single static exposure). The substrate table WT is then shifted in the X and/or Y direction so that a different target portion C can be exposed. In step mode, the maximum size of the exposure field limits the size of the target portion C imaged in a single static exposure.
2. In scan mode, the support structure MT and the substrate table WT are scanned synchronously while a pattern imparted to the beam PB is projected onto a target portion C (i.e. a single dynamic exposure). The velocity and direction of the substrate table WT relative to the support structure MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.
3. In another mode, the support structure MT is kept essentially stationary holding a programmable patterning device, and the substrate table WT is moved or scanned while a pattern imparted to the beam PB is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

It is a feature of embodiments that an image sensor 10 may be positioned at wafer table WT of a lithographic apparatus, such as that of FIG. 1, and used to sense the image projected from by the apparatus via the patterning device MA.

The sensor may, for example, be used during a measurement phase before exposure of the substrate. The substrate table may be moved so that the wave front sensor 10 is positioned under the projection system PS. Then, radiation is projected onto the wave front sensor 10. The signals from the sensor are provided to a processor 12, which can process the signals for any desired purpose, for example to calculate aberrations of the projection system PS. The calculated aberrations can, for example, be used to characterize or adjust the lens.

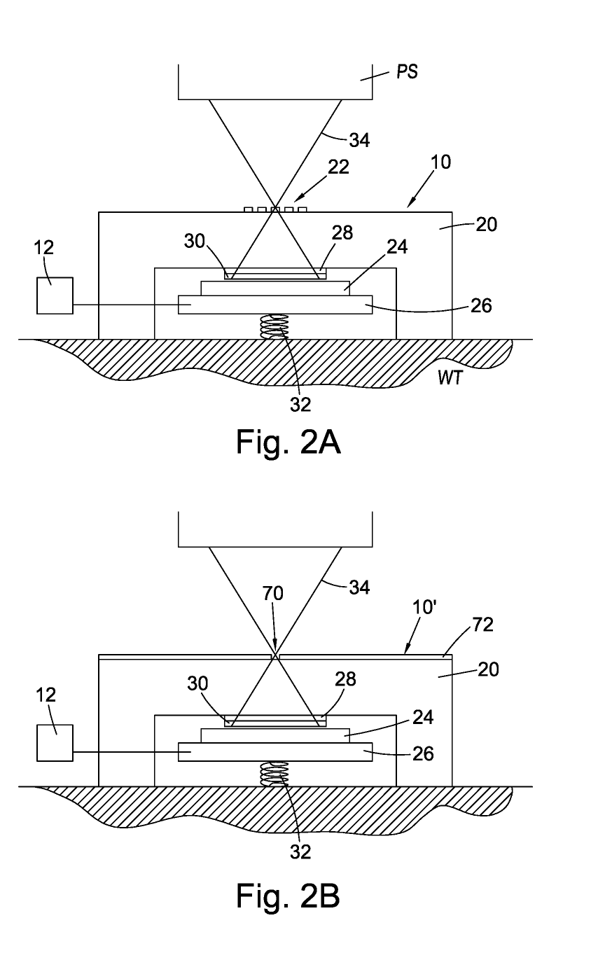

FIG. 2A is a schematic illustration of an embodiment of the wave front sensor 10. The wave front sensor 10 comprises a transparent carrier plate 20, and a camera 24, 26 configured at an opposite side of the carrier plate 20. The carrier plate may, for example, comprise fused silica, sapphire or any other suitable material. The grating 22 may comprise a plurality of bars that are not transparent to the radiation involved. In an embodiment the carrier plate 20 is transparent to DUV or EUV radiation as appropriate. The camera 24, 26 comprises a camera chip 24 arranged on a printed circuit board 26. The camera chip 24 comprises a plurality of pixels that are sensitive to visible light. The camera chip 24 may be for example a CMOS chip. The wave front sensor 10 further comprises a conversion layer 28 between the carrier plate 20 and the camera 24, 26. The conversion layer 28 is configured to convert DUV or EUV radiation into visible light. The wave front sensor 10 also includes a radiation filter 30 between the conversion layer 28 and the camera 24, 26. In an embodiment the wave front sensor 10 comprises a spring 32 configured to press the camera 24, 26 and the radiation filter 30 against the conversion layer 28. In one embodiment the conversion layer 28 is fixed to the carrier plate 20 (by gluing or other method). In another embodiment, there is an air layer between the carrier plate 20 and the conversion layer 28, and in such embodiment the conversion layer 28 is not fixed directly to the carrier plate 20.

FIG. 2B is a schematic illustration of an alternative embodiment of a sensor 10′, which is similar to the sensor of FIG. 2A and in which like components are indicated by like reference numerals. Instead of the grating 22, the sensor 10′ comprises a pinhole 70 in a non-transparent layer 72 deposited on top of the carrier plate 20. Radiation coming through the pinhole 70 is detected by the camera 24.

It is a feature of certain embodiments that the filter 30 has an optical property, for example transmissivity, reflectivity, absorption or fluorescence, that varies with lateral position. The variation of the optical property is such as to at least partially compensate for a non-uniform illumination of the image plane by the illumination system IL that may occur. For example, in some embodiments the illumination system IL may provide higher illumination levels, at the operating wavelength, towards the centre of the image plane than towards the edges of the image plane. By providing a filter 30 having an optical property (for example, transmissivity, reflectivity, absorption or fluorescence) that varies with lateral position, such variations in the illumination levels can be at least partially compensated for, such that the illumination levels at the pixels of the camera chip 24 are more uniform than they would have been in the absence of the filter 30.

Reference to an optical property is not limited to being a property at visible wavelengths, but may refer to a property at any operating wavelength or other relevant wavelength, for example DUV or EUV wavelengths if the filter is used to filter electromagnetic radiation at those wavelengths. In some embodiments the filter is used to filter visible light, for example visible light obtained from a fluorescent conversion layer that converts EUV, DUV or radiation at other wavelengths to visible light for detection.

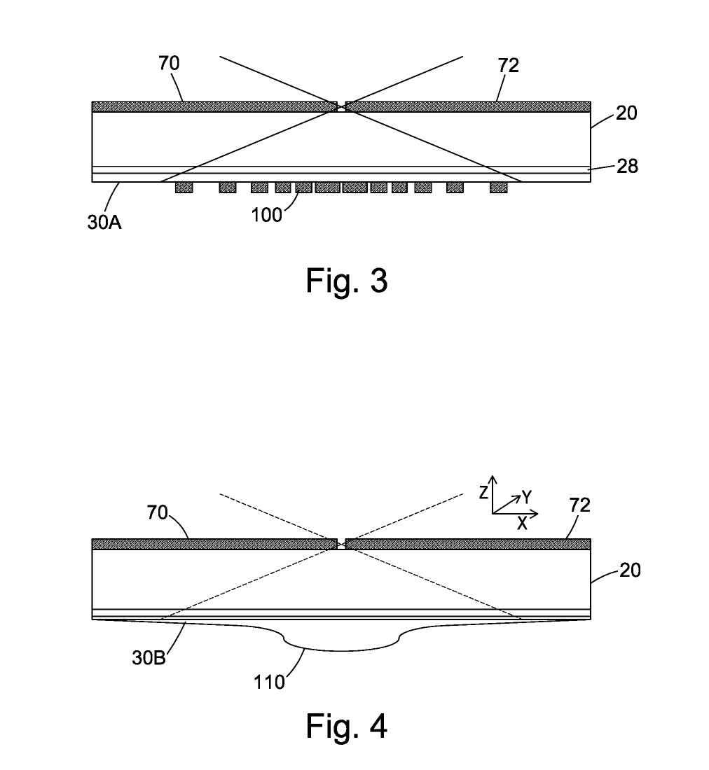

A filter 30a according to one embodiment is illustrated schematically in FIG. 3 installed in the sensor 10′ of FIG. 2B. Only some of the components of the sensor are shown in FIG. 3 for clarity. In this embodiment, the filter 30a includes a plurality of optical absorbing structures 100 that are distributed across the body of the filter in a desired distribution. It can be seen that there is a greater concentration of the structures 100 at the centre of the filter than towards the edges of the filter, thus providing a relative decrease in transmissivity at the centre of the filter compared to the edges of the filter. That relative decrease in transmissivity can at least partially compensate for a non-uniformity of illumination of the image plane.

The expected non-uniformity of the image plane can be measured directly or can be calculated based on properties of the illumination system, and the filter characteristics (for example distribution of the structures 100) can be selected based on the measurements or calculations.

Each of the structures 100 are of substantially the same thickness, and it is the distribution of the structures that determines the variation of transmissivity across the filter. At least some of the structures 100, as shown in FIG. 3 can be deposited in contiguous fashion such that two or more of the structures adjoin to form single larger structures.

The individual structures 100 of the embodiment of FIG. 3 have a diameter (in a direction parallel to the image plane) of around 5 μm, although individual structures can be deposited contiguously to form larger combined structures. In comparison, individual pixels of the camera 24, 26 in this embodiment are of size 50 μm by 50 μm. Thus, the individual structures are significantly smaller than the pixels. The structures can have suitable shape, for example square, rectangular, round or a combination of squares, rectangles, circles or other suitable shapes. In alternative embodiments, structures and camera pixels can be of any suitable size.

The structures 100 can have a high level of absorption in some embodiments such that no or little light at the operating wavelength passes through the structures 100. It is then the number and distribution of structures that determines the overall transmissivity, rather than a variation of transmissivity or other optical property between individual ones of the structures.

In the embodiment of FIG. 3, the filter is used to filter visible light obtained from the conversion layer 28 before it reaches the camera 24, 26, and the visible light can be considered to be at the operating wavelength of the filter. In alternative embodiments, the filter may be configured to filter radiation at other wavelengths, for example EUV or DUV radiation directly, for instance without use of a fluorescent conversion layer or before conversion at such conversion layer.

In alternative embodiments the structures 100 can be reflective, transmissive or fluorescent to provide the desired filtering effect, and such reflective, transmissive or fluorescent structures, when installed in a suitable sensor type, can be used as appropriate to ensure that a desired level of radiation or desired level of attenuation of radiation at a measurement wavelength is obtained at the camera.

The filter of the embodiment of FIG. 3 can be considered to be a digital filter. A filter 30b according to an alternative embodiment is illustrated schematically in FIG. 4. The filter 30b comprises a layer of absorbing material 110 that absorbs radiation at a filter operating wavelength (for example, EUV, DUV or, in the embodiment of FIG. 4, visible wavelengths). The material in this embodiment is such that the amount of absorption at a particular point on the filter 30b depends on the thickness of material at that point. The filter of the embodiment of FIG. 3 can be considered to be an analogue filter.

In the embodiment of FIG. 4 it can be seen that the layer of material 110 is thickest around the centre of the filter 30b, and thinner away from the centre. In this embodiment, the layer 110 does not extend to the edges of the filter 30a and the material is not deposited at or near the edges. Thus in this embodiment the layer of material 110 does not completely cover the surface of the filter body. In other embodiments, the layer of material 110 does cover the surface of the filter body, with the thickness of the layer varying with lateral position. For some embodiments, in which the layer of material 110 is formed of TiN or CrOx the thickness at the centre of the filter 30b is in the range 20 nm to 80 nm.

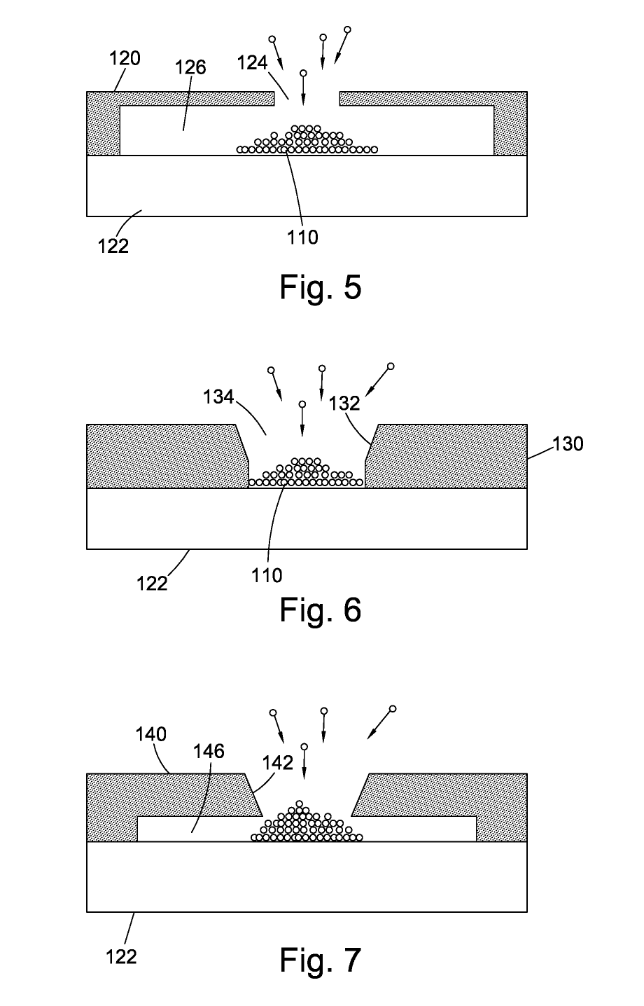

The filter of the embodiment of FIG. 4, and similar embodiments, can be formed using a variety of methods. One such method is illustrated schematically in FIG. 5. According to the method a hard mask 120 is provided on a substrate 122 that forms the body of the filter 30b. An orifice 124 is provided in the hard mask 120 through which the material 110 is deposited on the surface of the substrate 122. Any suitable process can be used to deposit the material 110 through the orifice 124, for example a vapour deposition or sputter process.

A gap 126 is provided between the orifice 124 and the surface of the substrate 122. The gap 126 has a wider lateral extent than the orifice 124 and opens out beneath the orifice 124. In this embodiment, the gap 126 extends over substantially the whole lateral area of the substrate 122. The presence of the gap 126 can ensure that the material 110 can be deposited on the surface of the substrate 122 with a desired distribution, in this case a desired variation of thickness with lateral position, and that the material 110 can be deposited over an area wider than the lateral extent of the orifice 124. The size of the orifice 124, for example the lateral extent and the depth of the orifice 124, and the gap 126, together with the parameters of the deposition process, can be selected to provide a desired distribution of material 110 on the surface of the substrate 122. After deposition of the material 110 the mask 120 can be removed using known techniques, for example, by dissolving the mask 120 using suitable chemical processing, or by mechanically separating the mask 120 and substrate 122, to leave the filter 30b. In some embodiments, the image sensor 24 may have an area in a range 5 mm×5 mm to 30 mm×30 mm or any rectangular sizes in between. In at least some of those embodiments, orifice diameters are in a range 0.5 mm to 10 mm, and sizes of the gap are in a range 0.8 mm to 20 mm.

Any suitable material can be used as material 110, for example a metal (e.g. Cr or Al), a semiconductor (for example, Si or Ge), a metal oxide or metal nitride (e.g. TiN). It will be understood that the specific examples of metals, semiconductors and metal nitrides given are by way of illustration only, and any other suitable metals, semiconductors, metal oxides or metal nitrides can be used in other embodiments.

An alternative method for forming the filter 30b is illustrated in FIG. 6. In this and similar embodiments, no gap or a reduced gap is provided between a mask 130 and the substrate 122. In this embodiment, the side wall 132 of an orifice 134 in the mask 130 is shaped to provide a desired distribution of the material 110 on the substrate 122. In this embodiment the side wall is shaped such that the orifice 134 has a wider diameter towards the top of the mask 130 than toward the bottom of the mask 130. The orifice 134 narrows towards the surface of the substrate 122. At least part of the side wall 132 is inclined at a selected angle to the surface of the substrate 122, in this case an oblique angle. Thus at least part of the side wall 132 of the mask 130 is not perpendicular to the substrate 122 in this embodiment.

The deposition process itself, the removal of the mask and the material 110 that may be used in this embodiment are the same or similar to those that may be used for the embodiment of FIG. 5. The shape of the side walls and the thickness of the mask, and/or the parameters of the deposition process, can be selected to provide a desired distribution of material 110 on the surface of the substrate 122.

A further alternative embodiment for forming the filter 30b is illustrated in FIG. 7. In this case, a gap 146 is provided between a mask 140 and the substrate 122, and the side wall 142 of the mask 140 has a desired shape and is not perpendicular to the substrate. Thus, the embodiment of FIG. 7 provides a combination of features of the embodiment of FIG. 5 and the embodiment of FIG. 6, as it includes a gap between the mask 140 and the substrate 122 and also includes a shaped, non-perpendicular side wall 142, with the gap and the shape of the side wall being selected to provide a desired distribution of the material 110 on the substrate 122.

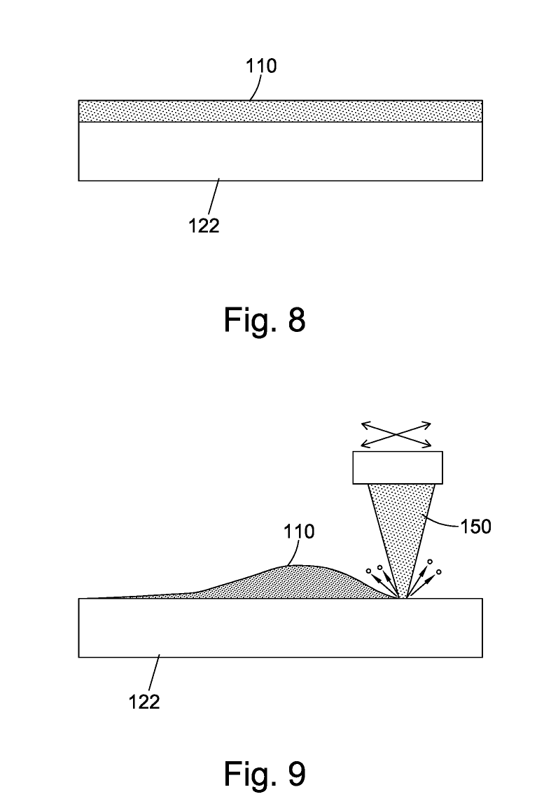

A further alternative process for forming the filter 30b is illustrated in FIGS. 8 and 9. In a first stage of the process, illustrated in FIG. 8, a layer of the material 110 of a desired thickness is deposited on the substrate 122 using any suitable deposition technique, for example vapour deposition or sputtering. In this embodiment the material is an at least partially absorbing material, in this case TiN, but it could equally be a reflective or fluorescent material in other embodiments.

At the next stage of the process, illustrated in FIG. 9, the thickness of the layer of material 110 is selectively altered as a function of position on the substrate 122. In this embodiment, the altering of the thickness comprises removal of at least part of the layer of material 110, in this case using an ion beam process to remove at least part of the layer. An ion beam source 150 is moved in the plane of the substrate (referred to as the x-y plane in this case) and selective variation of the intensity of the applied ion beam (which can comprise switching on or off, or selectively interrupting, the ion beam in some cases) is used to selectively remove the material 110. The selective removal of material 110 provides a desired distribution of the material on the substrate, in this case a desired thickness profile, thereby to provide a desired variation of transmission as a function of position.

The process used to shape the layer of material 110 is not limited to ion beam figuring and in other embodiments any suitable other process can be used to shape and or selectively remove the material 110 on the substrate 122, for example any one or more of selective chemical treatment, melting or reflow techniques, laser or other electromagnetic treatment, or mechanical treatment.

In alternative embodiments, features of the embodiments of FIGS. 5, 6, 7, 8 and/or 9 can be provided in any desired combination. For example, deposition of the material 110 using a mask as in the embodiments of FIG. 5, 6 or 7 can be combined with subsequent removal and/or shaping of the material 110 using techniques of the embodiment of FIGS. 8 and 9. Similarly, in some alternative embodiments features of the embodiments of FIG. 3 and FIGS. 8 and 9 can be provided in any desired combination. For instance, at least one layer of material may be deposited and then selectively removed or shaped to provide a digital-type filter with radiation at the relevant wavelength being either substantially completely blocked or being allowed to pass substantially unhindered by the material, depending on position.

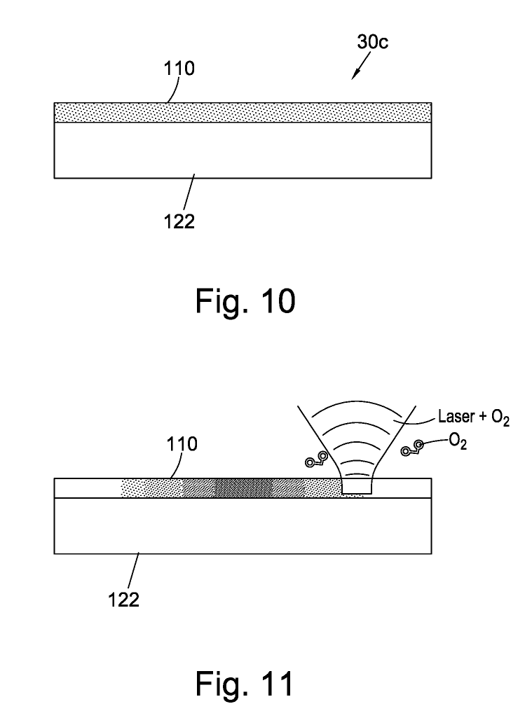

A filter 30c according to an alternative embodiment, and a process for its formation is illustrated schematically in FIGS. 10 and 11.

At a first stage of the process, illustrated in FIG. 10, a layer of material 110 of a desired thickness is deposited on the substrate 122 using any suitable deposition technique, for example vapour deposition or sputtering. A homogeneous layer of material of substantially constant thickness is deposited in the embodiment of FIG. 10. In this embodiment the material is silicon, but any other suitable material could be used in other embodiments.

At the next stage of the process, illustrated schematically in FIG. 11, an optical property of the material is altered selectively to provide a variation of the optical property with lateral position on the substrate 122. In the embodiment of FIGS. 10 and 11 the optical property is transmissivity or absorption, but any other suitable optical property, for example reflectivity or fluorescence, may be altered in alternative embodiments.

In the embodiment of FIG. 11, the process to selectively alter the transmissivity comprises selectively applying laser radiation to a surface of the material 110 in an oxygen-rich atmosphere provided at the surface of the material 110. The process provides selective oxidation, and thus bleaching, of the silicon thereby to provide a desired variation of transmissivity with lateral position on the substrate 122, thus forming the filter 30c.

Any other suitable process for altering at least one optical property of the material 110 can be used in other embodiments, for example selectively applying electromagnetic, for instance laser, radiation and/or performing a chemical treatment. The process may comprise a selectively applied photo-activated chemical reaction.

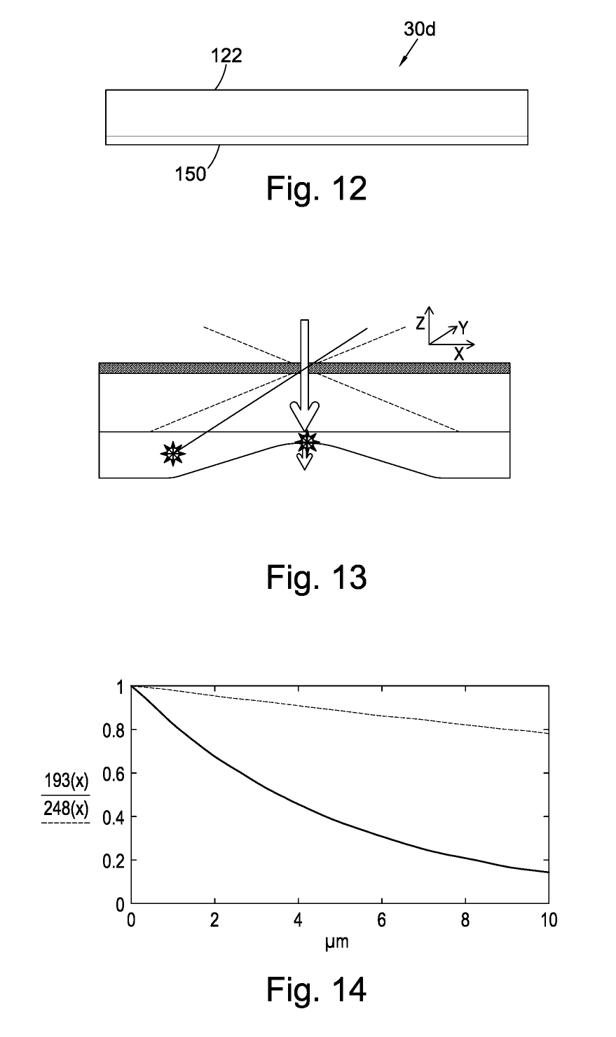

A filter 30d according to an alternative embodiment is illustrated schematically in FIG. 12. In this case, the filter 30d is in the form of a layer of fluorescent material 150 deposited on substrate 122. The fluorescent layer can be used to convert to radiation at an operating wavelength, for example EUV or DUV radiation, to visible light or light of any other suitable wavelength that can be detected by the camera 24, 26 or any other suitable measurement device. In some embodiments that filter 30d is used in place of conversion layer 28 and no separate conversion layer may be required.

The layer of fluorescent material 150 of the filter 30d is of a suitable thickness such that fluorescence varies in a desired manner with angle of incidence of applied radiation at an operating wavelength. In the embodiment of FIG. 12, the thickness of the layer of fluorescent material is less than the absorption length of the fluorescent material. That has the effect that radiation that passes through the material 150 in a perpendicular direction experiences less absorption, and thus less fluorescence, than radiation that passes through the material at non-perpendicular angle. In the embodiment of FIG. 12, the material is Lumilass G9 and the thickness of the layer of the material is 1 μm. For radiation at an operating wavelength, there is absorption rate of 18.1% for an angle of incidence of 90 degrees and an absorption rate of 33% for an angle of incidence of 60 degrees. Thus there is a higher rate of absorption, and thus higher fluorescence, for radiation received at an angle other than 90 degrees than for radiation received at an angle of incidence of 90 degrees to the substrate. FIG. 14 is a graph of transmission of radiation, on a normalised scale between 0 and 1, as a function of absorption length of beams applied to a layer of fluorescent material in the form of Lumilass G9. The solid curve shows the transmission of 193 nm radiation in Lumilass G9 according to the Beer-Lambert law. For x=1 μm, there is a drop in transmission of the 193 nm radiation to 0.819 (i.e. in this case 0.181, or 18.1%, is absorbed). For x=2 μm (equal to an absorption length in a 1 μm layer under an angle of incidence of 60°) there is a transmission of 0.67 (i.e. in this case 0.33 (33%) of the radiation is absorbed). Under the assumption that the fluorescence is proportional to the absorption one could get a factor of around 1.8 between centre and off-axis beams. For radiation of 248 nm (dashed line) similar effects are seen. Due to the smaller absorption coefficient of the Lumilass G9 at 248 nm, the Lumilass G9 layer would need a thickness of 8 μm to obtain the same effects as for 193 nm radiation with a 8 μm layer thickness. The effects can be self-aligning, no alignment of the filter with respect to a pinhole or other structure is necessary.

In the embodiments of FIGS. 2A and 2B, for points away from the centre of the image plane, radiation at the operating wavelength is received at an angle of incidence other than 90 degrees, with the angle of incidence increasing with distance away from the centre of the image plane. In the absence of other factors, the intensity of the radiation also generally decreases with distance from the centre of the image plane and it is that non-uniformity that the filter 30d can at least partially correct or compensate for by providing increased fluorescence with increasing distance from the centre of the image plane.

A filter 30e according to a further alternative embodiment is illustrated schematically in FIG. 13. As was the case with the embodiment of FIG. 12, the filter 30e is in the form of a layer of fluorescent material 160. The fluorescent layer can be used to convert to radiation at an operating wavelength, for example EUV or DUV radiation, to visible light or light of any other suitable wavelength that can be detected by the camera 24, 26 or any other suitable measurement device. In some embodiments that filter 30e is used in place of conversion layer 28 and no separate conversion layer may be required.

In the embodiment of FIG. 13, a homogeneous layer of the fluorescent material 160 is formed on carrier plate 20, acting as a substrate, and then techniques such as those as described in relation to the embodiment of FIG. 9 and similar embodiments, or other suitable methods, are used to selectively alter the thickness of the layer of fluorescent material by removing some of the fluorescent material, such that the thickness of the fluorescent material varies with lateral position. For example, the shape of the fluorescent glass layer can be obtained by mechanical polishing or ion beam figuring or any other suitable removal or deposition methods.

In alternative embodiments, the layer of material 160 may be deposited in a selective fashion such as to provide the desired thickness variation, without requiring subsequent removal of material. In some alternative embodiments, the fluorescent layer is not formed on the carrier plate 20 but instead is formed as a separate component, and/or is formed on another substrate.

In the embodiment of FIG. 13, in the centre of the filter 30e the thickness of the layer of fluorescent material 160 is less than the absorption length of the radiation at the relevant wavelength (for example, EUV or DUV radiation). Towards the edges of the filter 30e, the thickness of the fluorescent material is equal to or greater than the absorption length of the radiation at the relevant wavelength, such that substantially all of the radiation at the relevant wavelength (for example, EUV or DUV radiation) is converted into visible light. Thus, the filter 30e can at least partially correct or compensate for non-uniformity of illumination by providing increased fluorescence with increasing distance from the centre of the image plane.

While specific embodiments of the invention have been described above, it will be appreciated that the invention may be practiced otherwise than as described. The description is not intended to limit the invention.

1-8. (canceled)

9. A filter of a lithographic system, the filter comprising a body and at least one structure in or on the body, wherein the at least one structure has a substantially constant thickness and provides a filtering effect and wherein there is at least one selected from a), b), or c):
a) the at least one structure comprises a plurality of transmissive, reflective, absorbing or fluorescent structures each having substantially the same thickness and distributed to provide a desired filtering effect;
b) the at least one structure has a variation of at least one optical property with position;
c) the at least one structure comprises a fluorescent layer that provides variation of at least one fluorescence property with position and/or angle of incidence.

10. A filter according to claim 9, wherein the at least one structure comprises the plurality of transmissive, reflective, absorbing or fluorescent structures and the desired distribution of the structures comprises a desired concentration of the structures as a function of position.

11. (canceled)

12. A filter according to claim 9, wherein the at least one structure has the variation of at least one optical property with position and the optical property that varies with position comprises at least one selected from: transmissivity, absorption, reflectivity or fluorescence.

13. A filter according to claim 9, wherein the at least one structure comprises the fluorescent layer and the fluorescent layer has a thickness less than an absorption length of radiation at a filter wavelength for at least some positions on the filter.

14. An image sensor for a lithographic apparatus comprising a detector array and the filter according to claim 9.

15. A lithographic apparatus comprising:
an illumination system configured to provide a beam of radiation;
a support structure configured to support a patterning device, the patterning device serving to impart the radiation beam with a pattern in its cross-section;
a substrate table configured to hold a substrate;
a projection system configured to project the patterned radiation beam to provide an image at the substrate table; and
the sensor according to claim 14 installed on the substrate table to sense at least a region of the image.

16. A filter according to claim 10, wherein the concentration of structures is greater at a central portion of the filter than towards an edge of the filter.

17. A filter according to claim 9, wherein the at least one structure comprises the plurality of transmissive, reflective, absorbing or fluorescent structures and the plurality of structures have a high level of absorption such that no or little radiation passes through the structures at an operating wavelength.

18. A filter according to claim 9, wherein the at least one structure comprises the fluorescent layer and the fluorescent layer has a thickness selected to provide a desired variation of fluorescence with angle of incidence.

19. A filter according to claim 9, wherein the at least one structure comprises the fluorescent layer and the fluorescent layer is arranged such as to provide a variation of fluorescence efficiency with position.

20. A filter according to claim 9, wherein the at least one structure comprises the plurality of transmissive, reflective, absorbing or fluorescent structures.

21. A filter according to claim 9, wherein the at least one structure comprises the fluorescent layer.

22. A method of forming a radiation filter for use in a lithographic system, the method comprising:
obtaining a filter body; and
forming at least one structure in or on the body, wherein the at least one structure has a substantially constant thickness and provides a filtering effect and wherein there is at least one selected from a), b) or c):
a) the at least one structure comprises a plurality of transmissive, reflective, absorbing or fluorescent structures each having substantially the same thickness, and the forming comprises providing a desired distribution of the structures to provide a desired filtering effect;
b) forming the at least one structure comprises altering at least one optical property to provide a variation of the optical property with position;
c) the at least one structure comprises a fluorescent layer that provides variation of at least one fluorescence property with position and/or angle of incidence.

23. A method according to claim 22, comprising providing of the desired distribution of the structures and the providing of the desired distribution of the structures comprises providing a desired concentration of the structures as a function of position.

24. A method according to claim 23, wherein the concentration of structures is greater at a central portion of the filter than towards an edge of the filter.

25. A method according to claim 22, wherein the at least one structure comprises the plurality of transmissive, reflective, absorbing or fluorescent structures and at least some of the plurality of structures are deposited in a contiguous fashion such that two or more of the structures adjoin to form single larger structures.

26. A method according to claim 22, wherein the at least one structure has the variation of at least one optical property with position and the optical property that varies with position comprises at least one selected from: transmissivity, absorption, reflectivity or fluorescence.

27. A method according to claim 22, wherein the at least one structure comprises the fluorescent layer and the fluorescent layer has a thickness less than an absorption length of radiation at a filter wavelength for at least some positions on the filter.

28. A method according to claim 22, wherein the at least one structure comprises the plurality of transmissive, reflective, absorbing or fluorescent structures and the plurality of structures have a high level of absorption such that no or little radiation passes through the structures at an operating wavelength.

29. A method according to claim 22, wherein the at least one structure comprises the fluorescent layer and the fluorescent layer has a thickness selected to provide a desired variation of fluorescence with angle of incidence.

30. A method according to claim 22, wherein the at least one structure comprises the fluorescent layer and the fluorescent layer is arranged such as to provide a variation of fluorescence efficiency with position.

31. A method according to claim 22, wherein the at least one structure comprises the plurality of transmissive, reflective, absorbing or fluorescent structures each having substantially the same thickness, and the forming comprises providing the desired distribution of the structures to provide a desired filtering effect.

32. A method according to claim 22, wherein the at least one structure comprises the fluorescent layer that provides variation of at least one fluorescence property with position and/or angle of incidence.
